(19) United States
(12) Patent Application Publication
(10) Pub. No.: US 2024/0297149 A1
(43) Pub. Date: Sep. 5, 2024

(54) STACKED SEMICONDUCTOR DEVICE

(71) Applicant: Micron Technology, Inc., Boise, ID (US)

(72) Inventors: Bharat Bhushan, Taichung (TW); Akshay N. Singh, Boise, ID (US); Kunal R. Parekh, Boise, ID (US)

(21) Appl. No.: 18/426,271

(22) Filed: Jan. 29, 2024

Related U.S. Application Data
(60) Provisional application No. 63/449,702, filed on Mar. 3, 2023.

(51) Int. Cl. H01L 25/065; H01L 21/56; H01L 21/78; H01L 23/00; H01L 23/31; H01L 25/00; H10B 80/00

(52) U.S. Cl. CPC H01L 25/0657; H01L 21/561; H01L 21/78; H01L 23/3128; H01L 24/08; H01L 24/80; H01L 24/94; H01L 25/50; H10B 80/00; H01L 24/16; H01L 24/32; H01L 24/73; H01L 2224/08145; H01L 2224/16225; H01L 2224/32225; H01L 2224/73204; H01L 2224/80895; H01L 2224/80896; H01L 2224/94

(57) ABSTRACT

A semiconductor device assembly is provided. The semiconductor device assembly includes a logic die, a top memory die, and a one or more intermediate memory dies between the top memory die and the logic die. Front sides of the one or more intermediate memory dies at which active circuitry is disposed face a front side of the top memory die. Back sides of the one or more intermediate memory dies opposite the front sides face a back side of the logic die. In doing so, a cost-efficient, low-complexity semiconductor device can be assembled.

### CROSS-REFERENCE TO RELATED APPLICATION(S)

The present application claims priority to U.S. Provisional Patent Application No. 63/449,702, filed Mar. 3, 2023, the disclosure of which is incorporated herein by reference in its entirety.

### TECHNICAL FIELD

The present disclosure generally relates to semiconductor device assemblies and more particularly relates to a stacked semiconductor device.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly.

FIG. 2 illustrates a simplified schematic cross-sectional view of a semiconductor device assembly in accordance with an embodiment of the present technology.

FIGS. 3-6 illustrate simplified schematic perspective and cross-sectional views of a series of steps for fabricating semiconductor device assemblies in accordance with an embodiment of the present technology.

FIG. 7 illustrates a schematic view of a system that includes a semiconductor device assembly configured in accordance with an embodiment of the present technology.

FIG. 8 illustrates a method of fabricating a semiconductor device assembly in accordance with an embodiment of the present technology.

### DETAILED DESCRIPTION

Semiconductor devices are integrated into many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques for increasing the number of circuit elements on a semiconductor device without simultaneously increasing the size of the device. This development, however, may not be sustainable due to various challenges that arise from designing semiconductor devices with high circuit density. Thus, additional techniques may be required to continue the growth in capability of semiconductor devices.

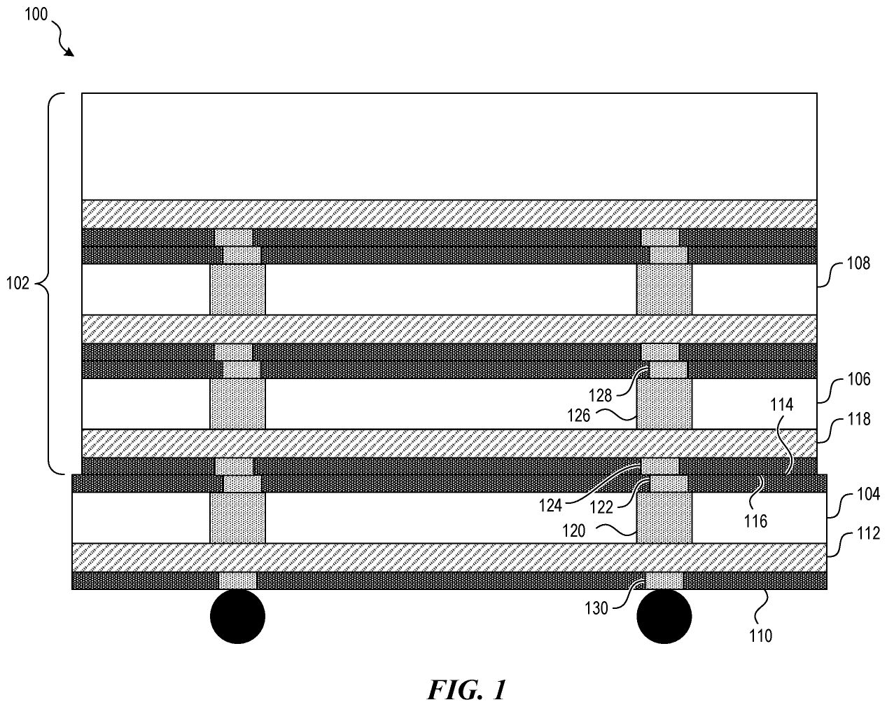

One such technique is the implementation of multiple circuit components within a single package. For example, stacked semiconductor devices enable multiple semiconductor dies to be stacked on top of one another to increase the number of circuit elements within a package without increasing its footprint. In some cases, individual semiconductor dies may be stacked on top of one another to produce a vertical stack of semiconductor dies. Alternatively, wafers containing multiple semiconductor dies can be stacked onto a base wafer adhered to a carrier wafer, and semiconductor die stacks can be singulated from the stack of wafers. The die stacks may then be packaged into a packaged semiconductor device to be implemented within a larger system. A design process for assembling semiconductor devices using these techniques, however, may be costly or time consuming. An example semiconductor device assembled using these techniques is shown in FIG. 1.

FIG. 1 illustrates a semiconductor device assembly 100 that includes a stack of semiconductor dies 102 (e.g., memory dies) assembled onto a semiconductor die 104 (e.g., a logic die). The semiconductor die 104 may be singulated from a wafer of semiconductor dies (e.g., logic dies) after the stack of semiconductor dies 102 is assembled onto the wafer of semiconductor dies. The stack of semiconductor dies 102 may be singulated from a stack of semiconductor wafers created by bonding wafers that include a plurality of semiconductor dies (e.g., wafer-wafer bonding). The wafers may be bonded in a front-to-back arrangement such that a front side (e.g., an active side) of a first wafer at which a metallization layer (e.g., including traces, lines, vias, or other connective circuitry) of the semiconductor dies is implemented is mounted to a back side (e.g., an inactive side) of a second wafer. The stack of semiconductor dies 102 may then be singulated from the stack of semiconductor wafers and coupled (e.g., chip-wafer bonded) with the semiconductor die 104 in a face-down arrangement (e.g., a front side of the semiconductor dies faces the semiconductor die 104). The semiconductor die 104 may similarly be configured in a face-down arrangement such that a front side 110 of the semiconductor die 104 at which metallization layer 112 is implemented faces away from the stack of semiconductor dies 102 and a back side 114 of the semiconductor die 104 opposite the front side 110 faces toward the stack of semiconductor dies 102. As a result, a front side 116 of the semiconductor die 106 at which metallization layer 118 is implemented may face the back side 114 of the semiconductor die 104. Similarly, the other dies in the stack of semiconductor dies 102 may be stacked in a front-to-back arrangement.

In some cases, instead of stacking the stack of semiconductor dies 102 from a stack of semiconductor wafers, each semiconductor die in the stack of semiconductor dies 102 can be singulated and individually stacked onto the semiconductor die 104. For example, the semiconductor die 106 of the stack of semiconductor dies 102 can be mounted (e.g., chip-wafer bonded) in a front-to-back arrangement to a wafer of semiconductor dies at the semiconductor die 104. Then, a mold or dielectric material can be disposed around the first semiconductor die 106 to form a reconstructed wafer, and a second semiconductor die 108 of the stack of semiconductor dies 102 can be mounted (e.g., chip-wafer bonded) in a front-to-back arrangement to the reconstructed wafer at the first semiconductor die 106. The process can then be repeated to create the stack of semiconductor dies 102.

The semiconductor die 104 can include through-silicon vias (TSVs) 120 that extend from the metallization layer 112 to the back side 114 of the semiconductor die 104. Contact pads 122 may be disposed on the back side of the TSVs 120 to enable an electrical connection with the semiconductor die 104. For example, the semiconductor die 106 may include contact pads 124 disposed at the front side 116 and electrically coupled with the metallization layer 118. The semiconductor die 106 can be coupled with the semiconductor die 104 at the contact pads 122 and the contact pads 124 to form interconnects that electrically couple the semiconductor dies. In aspects, the interconnects may include metal-metal interconnects (e.g., copper-copper (Cu—Cu) interconnects) formed through hybrid bonding and the semiconductor dies may be bonded through a dielectric material (e.g., silicon oxide, silicon nitride, silicon carbide, silicon carbon nitride, etc.).

One or more of the semiconductor dies from the stack of semiconductor dies 102 may similarly include TSVs 126 that are exposed at the back sides of the semiconductor dies (e.g., semiconductor die 106 and semiconductor die 108). Contact pads 128 can be disposed at the back sides of the semiconductor dies (e.g., semiconductor die 106 and semiconductor die 108) to enable interconnects to be formed to electrically couple respective semiconductor dies of stack of semiconductor dies 102. In this way, the stack of semiconductor dies 102 and the semiconductor die 104 may be assembled in a front-to-back arrangement such that respective metallization layers on pairs of coupled dies (e.g., metallization layer 112 of semiconductor die 104 and metallization layer 118 of semiconductor die 106, metallization layer 118 of semiconductor die 106 and a metallization layer of semiconductor die 108, etc.) may be separated by the TSVs in the lower die (e.g., TSVs 120, TSVs 126, etc.). Once assembled, connective elements (e.g., solder balls, solder bumps, wire bonds, etc.) may be disposed at contact pads 130 at the front side 110 of the semiconductor die 104 to provide external connectivity (e.g., power, ground, input/output (I/O) signals, etc.) to the semiconductor device assembly 100.

Various challenges may present themselves when designing stacked semiconductor devices using this technique, particularly with large die stacks. For example, in implementations where each semiconductor die is singulated and assembled individually onto the stack of semiconductor dies 102, the process may utilize a carrier wafer to process each wafer from which the dies are singulated. Moreover, each semiconductor die within the stack of semiconductor dies 102 may be individually stacked using dies that have been singulated from wafers and, thus, a dicing step may be needed for each semiconductor die in the stack. Further, yield may be reduced when stacking individual semiconductor dies due to the unreliability of chip-wafer hybrid bonds. For example, each hybrid bond between wafers (e.g., wafer-wafer bond) may have a yield of 95 percent, and a hybrid bond from a die to a wafer (e.g., chip-wafer bond) may be 90 percent effective. Thus, yield may be reduced as the number of chip-wafer bonds increases. In yet another aspect, the interconnects formed from chip-wafer bonding may have a larger misalignment than those formed through wafer-wafer bonding.

In implementations where the stack of semiconductor dies 102 is singulated from a stack of wafers, a carrier wafer may be used to support the stack of wafers during processing. In this way, the need for a carrier wafer may increase the cost to assemble the semiconductor device assembly 100. Moreover, the assembly of the semiconductor device assembly 100 may require a delamination step to remove the carrier wafer. Accordingly, the assembly of the semiconductor device assembly 100 may require undue cost or manufacturing time.

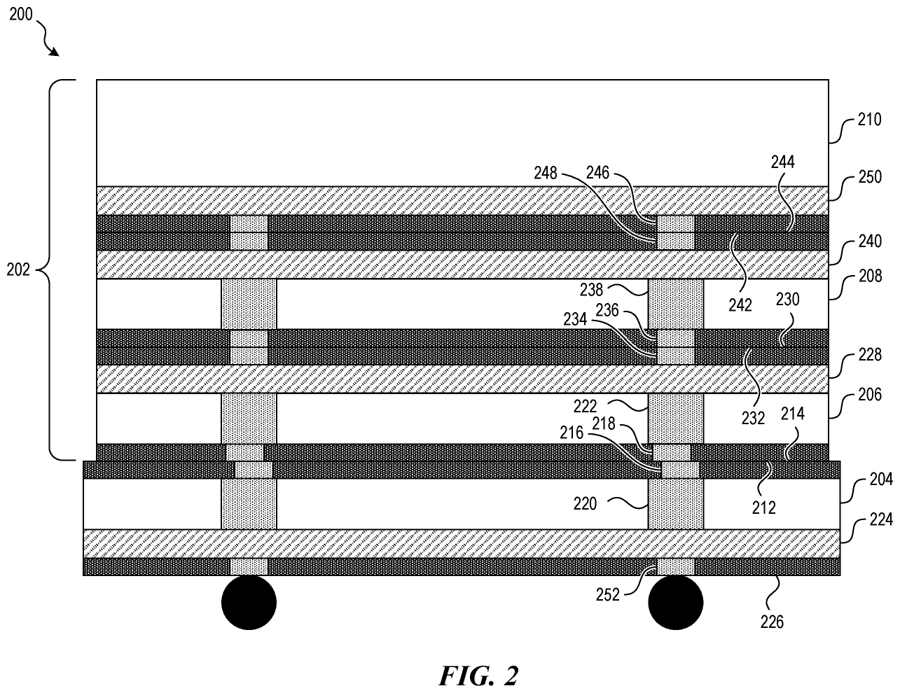

To address these drawbacks and others, various embodiments of the present technology provide semiconductor device assemblies that implement a stack of semiconductor dies. The semiconductor device assembly includes a logic die and a stack of memory dies electrically coupled with the logic die. A bottom memory die of the stack of memory dies is coupled to the logic die such that a back side of the logic die faces a back side of the bottom memory die. A top die in the stack of memory dies is coupled to another die in the stack of memory dies such that a front side of the top die faces a front side of the other die in the stack of memory dies. In doing so, a cost-efficient, low-complexity semiconductor device can be assembled, an example of which is shown in FIG. 2.

FIG. 2 illustrates a semiconductor device assembly 200 that includes a stack of semiconductor dies 202 (e.g., memory dies) assembled onto a semiconductor die 204 (e.g., a logic die). The semiconductor die 204 may be singulated from a wafer of semiconductor dies (e.g., logic dies) after the stack of semiconductor dies 202 is assembled onto the wafer of semiconductor dies. The stack of semiconductor dies 202 may be singulated from a stack of semiconductor wafers created by bonding wafers that include a plurality of semiconductor dies (e.g., wafer-wafer bonding). Once singulated, the stack of semiconductor dies 202 may be coupled (e.g., chip-wafer bonded) with the semiconductor die 204.

The stack of semiconductor dies may include a semiconductor die 206, a semiconductor die 208, and a semiconductor die 210. The semiconductor die 206 may be mounted to the semiconductor die 204 in a back-to-back arrangement such that a back side 212 of the semiconductor die 206 faces a back side 214 of the semiconductor die 204. The semiconductor die 204 and the semiconductor die 206 may include contact pads 216 and contact pads 218 formed at TSVs 220 and TSVs 222, respectively, to enable the formation of interconnects (e.g., metal-metal interconnects) that electrically couple the semiconductor dies. In this way, the contact pads 216, the contact pads 218, the TSVs 220, and the TSVs 222 may separate a metallization layer 224 (e.g., traces, lines, vias, or other connected structures formed through a back end of line process) at a front side 226 of the semiconductor die 204 and a metallization layer 228 at a front side 230 of the semiconductor die 206.

The semiconductor die 208 may be coupled to the semiconductor die 206 in a back-to-front arrangement such that a back side 232 of the semiconductor die 208 faces the front side 230 of the semiconductor die 206. The semiconductor die 206 may include contact pads 234 at the front side 230, and the semiconductor die 208 may include contact pads 236 at TSVs 238 exposed at the back side 232 of the semiconductor die 208 that electrically couple with the contact pads 234 to form interconnects (e.g., metal-metal interconnects formed from hybrid bonding) between the semiconductor dies. In aspects, the interconnects may be formed through wafer-wafer bonding and, thus, the interconnects may be better aligned than interconnects formed through chip-wafer bonding (e.g., between semiconductor die 204 and semiconductor die 206). Based on the arrangement of the semiconductor die 206 and the semiconductor die 208, a metallization layer 240 of the semiconductor die 208 may be separated from the metallization layer 228 of the semiconductor die 206 by the contact pads 234, the contact pads 236, and the TSVs 238. In this way, the TSVs 222 of the semiconductor die 206 may not separate the metallization layer 228 and the metallization layer 240.

The semiconductor die 210 can be coupled with the semiconductor die 208 such that a front side 242 of the semiconductor die 210 faces a front side 244 of the semiconductor die 208. Contact pads 246 and contact pads 248 may be disposed at the front side 242 and the front side 244 of the semiconductor die 208 and the semiconductor die 210, respectively, to form interconnects electrically coupling the dies. As illustrated in FIG. 2, the semiconductor die 210 need not include TSVs given that the front side 242 of the semiconductor die 210 faces the semiconductor die 208. Moreover, the face-to-face arrangement of the semiconductor die 210 and the semiconductor die 208 may result in a metallization layer 250 of the semiconductor die 210 and a metallization layer 240 of the semiconductor die 208 being separated by the contact pads 246 and the contact pads 248, but not the TSVs 238. To provide external connectivity to the semiconductor device assembly 200, connective elements can be disposed at contact pads 252 at the front side of the semiconductor die 204.

Although illustrated as two semiconductor dies, semiconductor die 206 and semiconductor die 208, other implementations are possible that include more or fewer semiconductor dies. For example, the semiconductor die 206 and the semiconductor die 208 could be replaced with a stack of semiconductor dies assembled in a back-to-front arrangement. Moreover, the semiconductor die 206 and the semiconductor die 208 could be replaced with a single semiconductor die having a front side facing the semiconductor die 210 and a back side opposite the front side and facing the semiconductor die 204. In this way, the total number of semiconductor dies in the stack of semiconductor dies 202 could equal 3, 4, 5, 6, 8, 10, 12, 14, or any other number of memory dies.

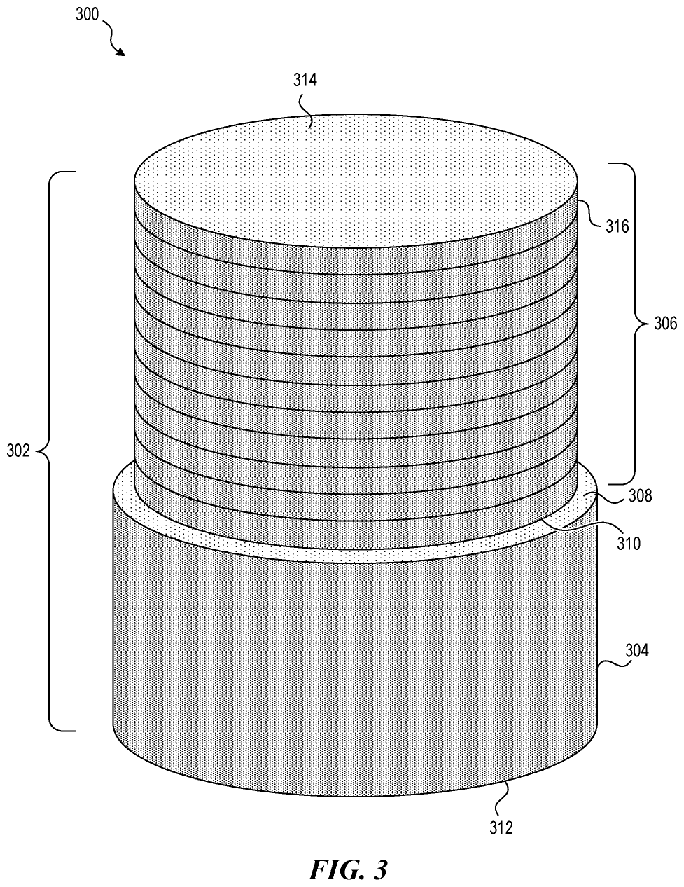

This disclosure now turns to a series of steps for fabricating semiconductor device assemblies in accordance with embodiments of the present technology. Specifically, FIGS. 3-6 illustrate simplified schematic perspective and cross-sectional views of a series of steps for fabricating semiconductor device assemblies in accordance with an embodiment of the present technology. The steps are illustrated with respect to specific embodiments for ease of description. However, the steps described with respect to FIGS. 3-6 could be performed to fabricate semiconductor device assemblies in accordance with other embodiments.

Beginning with FIG. 3 at stage 300, a perspective view of a stack of semiconductor wafers 302 is illustrated. The stack of semiconductor wafers 302 includes a first semiconductor wafer 304 and one or more semiconductor wafers 306 coupled (e.g., hybrid bonded) with the semiconductor wafer 304. Interconnects (e.g., metal-metal interconnects) may be formed between the semiconductor wafers in the stack of semiconductor wafers 302. For example, one or more of the semiconductor wafers in the stack of semiconductor wafers 302 may include contact pads at the front side and contact pads disposed at exposed TSVs (e.g., through wafer thinning) at the back side, and interconnects may be formed between these contact pads. The first semiconductor wafer 304 may be configured in a face-up arrangement such that a front side 308 of the semiconductor wafer 304 faces toward the semiconductor wafers 306. The semiconductor wafers 306 may be assembled (e.g., individually) into the stack of semiconductor wafers 302 in a face-down arrangement such that a front side 310 of the semiconductor wafers 306 faces toward the semiconductor wafer 304 (e.g., a bottom wafer of the semiconductor wafers 306 and the semiconductor wafer 304 are face-to-face). As a result, the semiconductor wafers 306 may be assembled in a front-to-back arrangement. Once assembled, the stack of semiconductor wafers 302 may have a first side that corresponds to a back side 312 of the semiconductor wafer 304 and a second side that corresponds to a back side 314 of a semiconductor wafer 316 of the stack of semiconductor wafers 306.

As illustrated, the semiconductor wafer 304 is a thick semiconductor wafer (e.g., relative to the semiconductor wafers 306). For example, the semiconductor wafer 304 may be larger than 100, 200, 300, 400, 500, or 600 microns, and the semiconductor wafers 306 may be less than 100, 90, 80, 70, 60, 50, 40, or 30 microns. In this way, the semiconductor wafer 304 may provide stability to the stack of semiconductor wafers 302 to enable the stack of semiconductor wafers 302 to withstand processing without requiring the stack of semiconductor wafers 302 to be adhered to a carrier substrate, thereby removing the cost of the carrier wafer from the total material cost and eliminating the step to remove the carrier wafer from the stack of semiconductor wafers 302 from the fabrication process.

Once assembled, the stack of semiconductor wafers 302 may be processed and singulated into individual semiconductor die stacks. For example, the stack of semiconductor wafers 302 may be adhered to back grinding tape (e.g., at semiconductor wafer 316) to enable the semiconductor wafer 304 to be thinned. The stack of semiconductor wafers 302 may be flipped so that the semiconductor wafer 316 can be adhered to the back grinding tape at the back side 314 and the back side 312 of the semiconductor wafer 304 is exposed for thinning. The back side 312 of the semiconductor wafer 304 can be thinned through any appropriate method, for example, using back grinding, chemical-mechanical planarization (CMP), or the like.

After thinning, the back grinding tape can be removed from the stack of semiconductor wafers 302 to enable the stack of semiconductor wafers 302 to be diced into multiple pluralities of stacked semiconductor dies. The stack of semiconductor wafers 302 may be adhered to dicing tape to enable the stack of semiconductor wafers 302 to be diced between the plurality of semiconductor dies to singulate multiple semiconductor die stacks. For example, the stack of semiconductor wafers 302 may be singulated to produce the stack of semiconductor dies 202 of FIG. 2. For instance, with reference to FIG. 2, the semiconductor wafer 304 may include the semiconductor die 210, the semiconductor wafer 316 may include the semiconductor die 206, and one of the semiconductor wafers between the semiconductor wafer 304 and the semiconductor wafer 316 may include the semiconductor die 208.

The multiple semiconductor die stacks may then be tested and assembled into packages. In some cases, a subset of the multiple stacks of semiconductor dies may be selected to be packaged into semiconductor devices. For example, the particular stacks of semiconductor dies selected to be packaged may be selected based on a quality of these die stacks. The quality of these die stacks may be determined by probing the semiconductor dies in the die stacks diced from the stack of semiconductor wafers 302. In this way, the highest-quality stacks of semiconductor dies, or “known good cubes,” may be selected for packaging to improve yield.

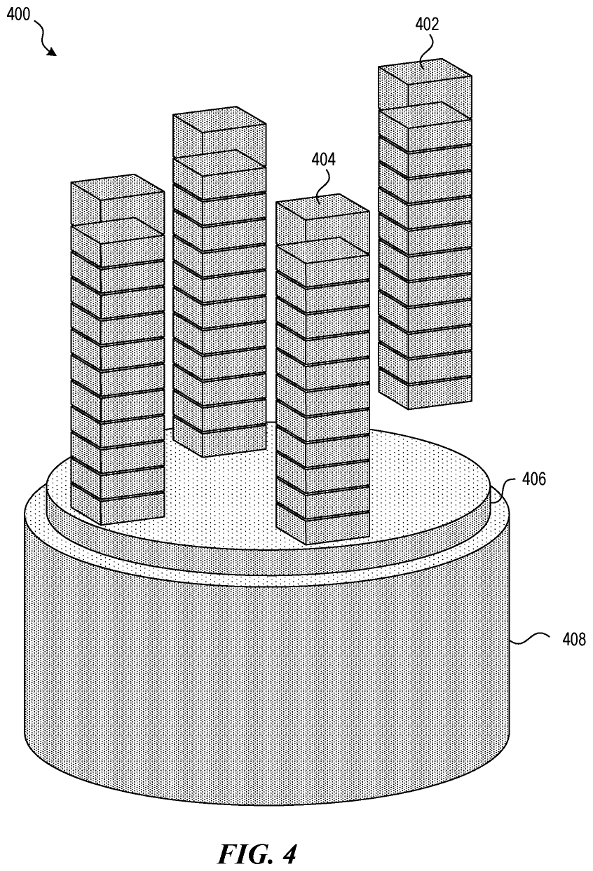

FIG. 4 illustrates a perspective view of stage 400, where the multiple stacks of semiconductor dies (e.g., a stack of semiconductor dies 402 and a stack of semiconductor dies 404) are assembled onto a wafer of semiconductor dies 406. In some cases, the multiple stacks of semiconductor dies can include memory dies and the wafer of semiconductor dies 406 can include logic dies. The multiple stacks of semiconductor dies may be electrically coupled to the wafer of semiconductor dies 406 at respective semiconductor dies (e.g., at different lateral locations). In some cases, the wafer of semiconductor dies 406 cannot be coupled, through wafer-wafer bonding, with the stack of semiconductor wafers 302 illustrated in FIG. 3 from which the multiple stacks of semiconductor dies are singulated due to a difference in configuration of these wafers. Thus, individual stacks of semiconductor dies are coupled with the wafer of semiconductor dies 406 through chip-wafer bonding. The multiple stacks of semiconductor dies may be coupled to the wafer of semiconductor dies 406 in a back-to-back arrangement such that a back side of respective bottom semiconductor dies of the multiple stacks of semiconductor dies may face a back side of the wafer of semiconductor dies 406. In this way, interconnects may be formed between contact pads at a front side of the bottom semiconductor dies and contact pads disposed at exposed TSVs on the back side of the wafer of semiconductor dies 406. In aspects, the multiple stacks of semiconductor dies may be coupled with the wafer of semiconductor dies in a flipped arrangement relative to the arrangement shown in FIG. 3. For example, with reference to FIG. 3, a semiconductor die from the semiconductor wafer 316 may be a bottom semiconductor die in the stack of semiconductor dies 402, and a semiconductor die from the semiconductor wafer 304 may be a top semiconductor die in the stack of semiconductor dies 402.

The wafer of semiconductor dies 406 may be assembled onto a carrier wafer 408 to enable the semiconductor device assembly to withstand processing. In aspects, the wafer of semiconductor dies 406 may be fusion bonded to the carrier wafer 408 (e.g., in a face-down arrangement such that a front side of the wafer of semiconductor dies 406 faces toward the carrier wafer 408) through a dielectric material (e.g., silicon oxide, silicon nitride, silicon carbide, silicon carbon nitride, etc.) or adhered to the carrier wafer 408 through an adhesive. In some cases, fusion bonding the wafer of semiconductor dies 406 to the carrier wafer 408 through a dielectric material may increase the reliability of the semiconductor device assembly. For example, the semiconductor device assembly may be heated during various processing steps, and the dielectric material may be more resistant, relative to the adhesive, to damage caused by this heating. Moreover, in contrast to some other techniques, external contacts at a front side of the wafer of semiconductor dies 406 need not be disposed prior to attaching the carrier wafer 408. In this way, damage to the external contacts may be limited during processing and overall design flexibility can be increased.

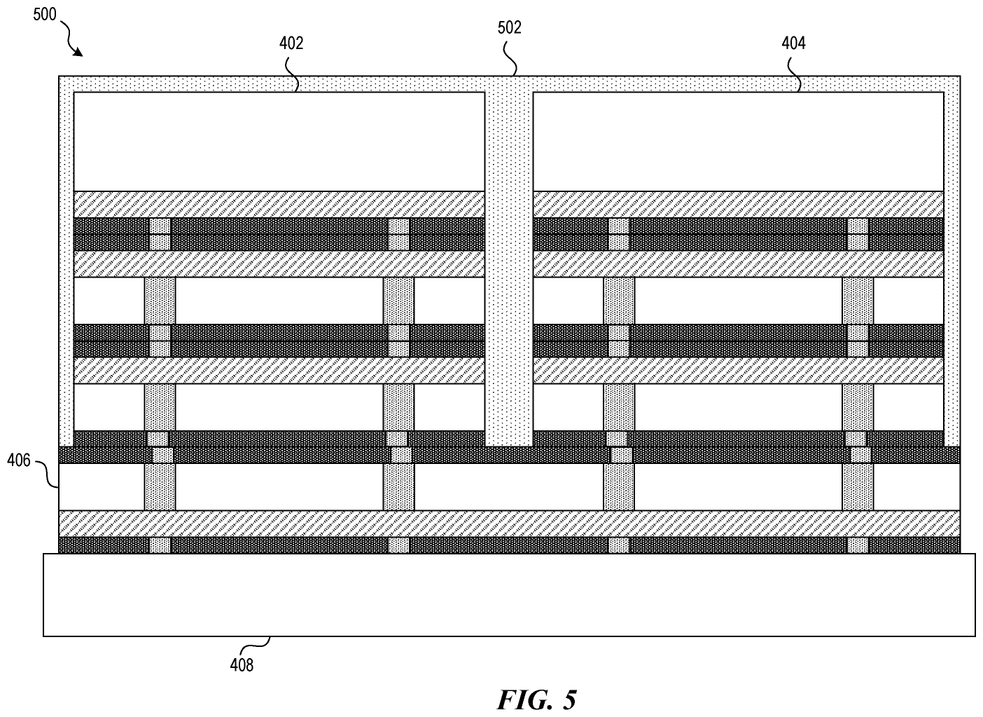

FIG. 5 illustrates a cross-sectional view of a stage 500 at which an encapsulant 502 is disposed around the stack of semiconductor dies 402 and the stack of semiconductor dies 404. The encapsulant 502 may include a mold resin, such as an epoxy mold compound (EMC), or a dielectric material, such as an oxide fill. The encapsulant 502 may be disposed on the wafer of semiconductor dies 406. In aspects, the encapsulant 502 may be disposed over the top of the stack of semiconductor dies 402 or the stack of semiconductor dies 404. In this way, the stack of semiconductor dies 402 or the stack of semiconductor dies 404 may be embedded in the encapsulant 502. In some cases, the encapsulant 502, the top of the stack of semiconductor dies 402, or the top of the stack of semiconductor dies 404 may be thinned through back grinding or CMP. The carrier wafer 408 may be removed from the wafer of semiconductor dies 406 and contact pads may be disposed at the front side to provide external connectivity to the semiconductor device assembly. The wafer of semiconductor dies 406 or the encapsulant 502 can be diced into individual die stacks to be packaged into semiconductor devices.

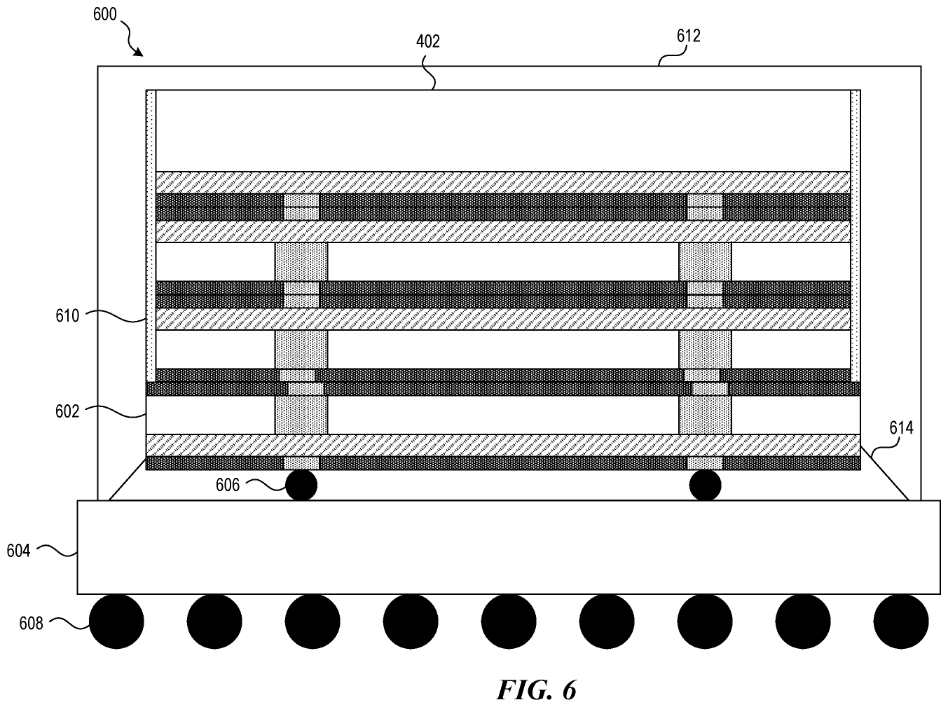

FIG. 6 illustrates a simplified schematic cross-sectional view of a semiconductor device assembly at stage 600, where the stack of semiconductor dies 402 and a semiconductor die 602 (e.g., singulated from the wafer of semiconductor dies 406 illustrated in FIG. 5) are packaged into a semiconductor device. For example, the semiconductor die 602 may be coupled with a package-level substrate 604 (e.g., printed-circuit board (PCB), interposer, etc.). Connective structures 606 (e.g., solder balls, solder bumps, conductive pillars, etc.) may be disposed between contact pads at a front side of the semiconductor die 602 and contact pads (not shown) at a top side of the package-level substrate 604 to implement interconnects that electrically couple the semiconductor die 602 and the package-level substrate 604. An underfill material 614 (e.g., capillary underfill) can be provided between the semiconductor die 602 and the package-level substrate 604 to provide electrical insulation to the interconnects and structurally support the assembly. The package-level substrate 604 may include internal routing circuitry (e.g., traces, lines, vias, and other connective structures) that connects the contact pads at the top surface to contact pads at the bottom side. Connective structures 608 may be disposed at the contact pads at the bottom side to provide external connectivity to other devices (e.g., on a motherboard).

The semiconductor device assembly may include sidewalls 610 (e.g., molded sidewalls, dielectric sidewalls, etc.) as a result of dicing through the encapsulant 502 of FIG. 5. As illustrated, the sidewalls 610 extend to the semiconductor die 602 and surround the stack of semiconductor dies 402. In other implementations, however, the encapsulant 502 of FIG. 5 may be disposed around the wafer of semiconductor dies 406 illustrated in FIG. 5 and, thus, the sidewalls may surround one or more sides of the semiconductor die 602. As illustrated, the sidewalls 610 do not extend over the stack of semiconductor dies 402 because, for example, the encapsulant 502 of FIG. 5 has been thinned or planarized down to expose the stack of semiconductor dies 402. In other implementations, however, the sidewalls 610 may extend over the top of the stack of semiconductor dies 402. The semiconductor device assembly can further include an encapsulant material 612 (e.g., mold resin compound or the like) that at least partially encapsulates the stack of semiconductor dies 402, the semiconductor die 602, or the package-level substrate 604 to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with a vertical stack of semiconductor dies, a plurality of semiconductor dies, a single semiconductor die, mutatis mutandis.

In accordance with one aspect of the present disclosure, the semiconductor devices illustrated in the assemblies of FIGS. 1-6 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

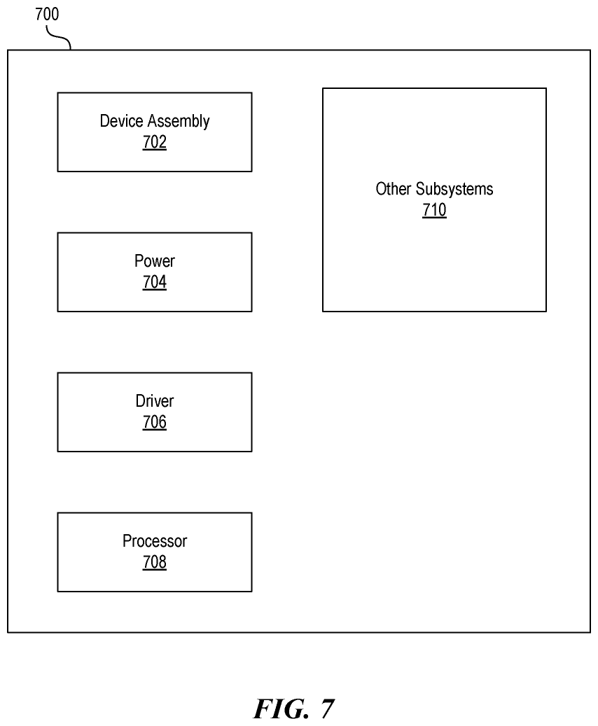

Any one of the semiconductor devices and semiconductor device assemblies described above with reference to FIGS. 1-6 can be incorporated into any of a myriad of larger and/or more complex systems, a representative example of which is system 700 shown schematically in FIG. 7. The system 700 can include a semiconductor device assembly 702 (e.g., a discrete semiconductor device), a power source 704, a driver 706, a processor 708, and/or other subsystems or components 710. The semiconductor device assembly 702 can include features generally similar to those of the semiconductor device assemblies described above with reference to FIGS. 1-6. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances, and other products. Components of the system 700 may be housed in a single unit or distributed over multiple, interconnected units (e.g., through a communications network). The components of the system 700 can also include remote devices and any of a wide variety of computer-readable media.

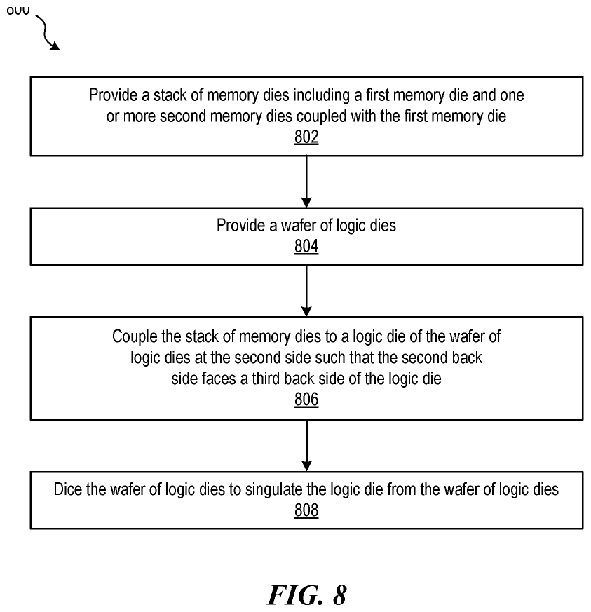

FIG. 8 illustrates an example method 800 for fabricating a semiconductor device assembly in accordance with an embodiment of the present technology. Although illustrated in a particular configuration, one or more operations of the method 800 may be omitted, repeated, or reorganized. Additionally, the method 800 may include other operations not illustrated in FIG. 8, for example, operations detailed in one or more other methods described herein.

At 802, a stack of memory dies is provided. The stack of memory dies includes a first memory die and one or more second memory dies coupled with the first memory die. A first front side of the first memory die faces one or more second front sides of the one or more second memory dies. The stack of memory dies includes a first side corresponding to a first back side of the first memory die and a second side corresponding to a second back side of one of the one or more second memory dies. At 804, a wafer of logic dies is provided. At 806, the stack of memory dies is coupled to a logic die of the wafer of logic dies at the second side such that the second back side faces a third back side of the logic die. At 808, the wafer of logic dies is diced to singulate the logic die from the wafer of logic dies. In doing so, an efficient and reliable semiconductor device assembly may be fabricated.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional interface (3DI) applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a logic die having a first front side at which first active circuitry is disposed and a first back side opposite the first front side; and
a top memory die having a second front side at which second active circuitry is disposed and a second back side opposite the second front side; and
one or more intermediate memory dies between the logic die and the top memory die, each of the one or more intermediate memory dies having a respective third front side at which third active circuitry is disposed and a respective third back side opposite the respective third front side,
wherein the respective third front side of each of the one or more intermediate memory dies faces the top memory die and the respective third back side of each of the one or more intermediate memory dies faces the logic die;
wherein a first one of the one or more intermediate memory dies is coupled to the logic die such that the respective third back side is directly bonded with the first back side, and
wherein a second one of the one or more stacked memory dies is coupled to the top memory dies such that the respective third front side is directly bonded with the second front side.

2. The semiconductor device assembly of claim 1, wherein the one or more intermediate memory dies comprise a single memory die.

3. The semiconductor device assembly of claim 1, wherein the first one of the one or more intermediate memory dies is coupled to the logic die through a hybrid bond.

4. The semiconductor device assembly of claim 1, wherein the top memory die is coupled to the second one of the one or more intermediate memory dies through a hybrid bond.

5. The semiconductor device assembly of claim 1, wherein the one or more intermediate memory dies comprises one or more dynamic random-access memory (DRAM) dies.

6. The semiconductor device assembly of claim 1, wherein the one or more intermediate memory dies includes eleven memory dies.

7. The semiconductor device assembly of claim 1, further comprising a molded sidewall surrounding the one or more intermediate memory dies and the top memory die.

8. A method for fabricating a semiconductor device assembly, comprising:
providing a stack of memory dies including a first memory die and one or more second memory dies with the first memory die,
wherein each memory die of the stack of memory dies is directly bonded with a respective memory die of the stack of memory dies,
wherein a first front side of the first memory die at which first active circuitry is disposed is faces one or more second front sides of the one or more second memory dies at which second active circuitry is disposed, and
wherein the stack of memory dies includes a first side corresponding to a first back side of the first memory die and a second side corresponding to a second back side of one of the one or more second memory dies;
providing a wafer of logic dies;
coupling the stack of memory dies to a logic die of the wafer of logic dies at the second side such that the second back side faces a third back side of the logic die; and
dicing the wafer of logic dies to singulate the logic die from the wafer of logic dies.

9. The method of claim 8, wherein providing the stack of memory dies comprises:
providing a first wafer of memory dies including the first memory die;
providing one or more second wafers of memory dies each including a respective second memory die of the one or more second memory dies;
coupling the one or more second wafers of memory dies to the first wafer of memory dies to form a stack of wafers,
wherein the one or more second front sides of the one or more second memory dies face the first front side of the first memory dies; and
dicing the stack of wafers to singulate the stack of memory dies.

10. The method of claim 9, further comprising:
dicing the stack of wafers to create multiple stacks of memory dies;
probing the multiple stacks of memory dies to determine a quality of the multiple stacks of memory dies; and
selecting the stack of memory dies from the multiple stacks of memory dies based on the quality.

11. The method of claim 8, further comprising:
disposing an encapsulant at the wafer of logic dies and around the stack of memory dies; and
dicing the encapsulant to singulate the stack of memory dies.

12. The method of claim 8, further comprising:
providing a carrier wafer; and
prior to coupling the stack of memory dies to the logic die, coupling the wafer of logic dies to the carrier wafer through a dielectric material such that a third front side of the wafer of logic dies faces the carrier wafer.

13. The method of claim 8, further comprising:
providing an additional stack of memory dies including a third memory die and one or more fourth memory dies coupled with the third memory die,
wherein a third front side of the third memory die faces one or more fourth front sides of the one or more fourth memory dies at which fourth active circuitry is disposed,
wherein the stack of memory dies includes a third side corresponding to a fourth back side of the third memory die and a fourth side corresponding to a fifth back side of one of the one or more fourth memory dies;
coupling the additional stack of memory dies to an additional logic die of the wafer of logic dies at the fifth side such that the fourth back side faces a fifth back side of the additional logic die; and
dicing the wafer of logic dies to singulate the additional logic die from the wafer of logic dies.

14. A semiconductor device assembly, comprising:
a logic die having a first conductive pad, a first metallization layer, and a first through-silicon via (TSV) coupling the first conductive pad with the first metallization layer; and
a stack of memory dies electrically coupled with the logic die, the stack of memory dies including:
a lower memory die having a second conductive pad, a second metallization layer, and a second TSV coupling the second conductive pad with the second metallization layer;
an upper memory die having a third conductive pad and a third metallization layer; and
a top memory die having a fourth conductive pad and a fourth metallization layer,
wherein the first conductive pad is coupled to the second conductive pad such that the first metallization layer and the second metallization layer are coupled through the first TSV, the first conductive pad, the second conductive pad, and the second TSV, and
wherein the fourth conductive pad is coupled to the third conductive pad such that the third metallization layer and the fourth metallization layer are coupled exclusive of any TSV.

15. The semiconductor device assembly of claim 14, wherein:
the lower memory die and the upper memory die are a same memory die;
the third metallization layer and the second metallization layer are a same metallization layer; and
the second conductive pad and the third conductive pad are different conductive pads on opposite sides of the same memory die.

16. The semiconductor device assembly of claim 14, wherein the first conductive pad and the second conductive pad are coupled through a hybrid bond.

17. The semiconductor device assembly of claim 14, wherein the top memory die is thicker than the upper memory die.

18. The semiconductor device assembly of claim 14, wherein the stack of memory dies comprises a stack of dynamic random-access memory (DRAM) dies.

19. The semiconductor device assembly of claim 14, wherein the top memory die does not include a TSV.

20. The semiconductor device assembly of claim 14, further comprising a molded sidewall surrounding the stack of memory dies.
